(19) United States
(12) Patent Application Publication
(10) Pub. No.: US 2017/0285107 A1
(43) Pub. Date: Oct. 5, 2017

(54) BATTERY STATE OF CHARGE ESTIMATOR

(71) Applicant: Wayne State University, Detroit, MI (US)

(72) Inventor: Nazri Gholam-Abbas, Bloomfield Hills, MI (US)

(21) Appl. No.: 15/511,948

(22) PCT Filed: Sep. 15, 2015
(86) PCT No.: PCT/IB2015/057102

§ 371 Date: Mar. 16, 2017

Related U.S. Application Data
(60) Provisional application No. 62/050,852, filed on Sep. 16, 2014.

(51) Int. Cl. G01R 31/36; H01M 10/46; H02J 7/16; H01M 4/134; H01M 4/52; H02J 7/00; H01M 10/42; H01M 10/48

(52) U.S. Cl. CPC G01R 31/3606; H01M 10/4257; H01M 10/46; H01M 10/486; H01M 4/134; H01M 4/52; H02J 7/0011; H02J 7/0021; H02J 7/0047; H02J 7/16; G01R 31/3662; G01R 31/3679

(57) ABSTRACT

A battery monitoring device includes a first coil positioned within a cell of a battery, a second coil positioned to be magnetically coupled to the first coil through active material that is contained within the cell, and a controller that is configured to apply an electrical current to one of the first and second coils, detect induced electrical current in the other of the first and second coils, and determine a state-of-charge (SOC) of the battery based on the induced electrical current.

### CROSS REFERENCE TO RELATED APPLICATIONS

This application claims priority to Provisional Patent Application 62/050,852 filed Sept. 16, 2014, which is hereby incorporated by reference in its entirety.

### TECHNICAL FIELD

The present disclosure relates to a method and apparatus to determine a battery state-of-charge (SOC), and more specifically for lithium-ion batteries.

### BACKGROUND

The unstable market and general long-term unsustainability of primary fuels (coal, oil, and gas) has brought research and development attention to alternative energy sources. However, due to the intermittency of the alternative energies (i.e., solar and wind), energy storage systems that can mitigate the problem of intermittency are at the forefront of global energy strategies. Transportation sectors are one major user of primary energy, and they are very much involved in electrification of the automobile, planes, and marine vehicles. The increase in electrification of the automobile has driven the industry to further optimization and cost reduction of batteries. There is therefore tremendous cost benefit in improving battery performance to optimize use and prevent their premature disposal, in not only the automotive industry, but in a vast array of other technologies that can benefit from improved battery technologies.

In recent years, lithium-ion batteries have attracted great attention toward applications in electronic devices, power tools, and electrification of the auto, to name a few. Lithium-ion batteries are desirable due to their high energy and power density (hence low weight), high cell voltage, slow loss of charge when not in use, and a wide temperature range of operation as compared with that of traditional batteries (such as Ni-MH battery and lead-acid battery). Due to these and other favorable properties, there has therefore been great attention (and resources) expended in implementing lithium-ion batteries in a wide variety of products.

In general, battery charge and re-charge is managed by a battery management system (BMS). The goal is to manage battery operation in order to maximize battery performance and avoid system inefficiencies. In BMS technology, however, the dynamics of cell impedance against SOC is often ignored, leading to inaccurate estimations of battery performance. Current BMS technologies often rely on passive reading of cell voltage and cell resistance as independent variables to estimate SOC. Coulomb counting also has been used in specific batteries without proper adjustment for battery aging, particularly, when unbalanced cells exist in the battery pack.

For instance, the resistance measurement or impedance tracker methodology is inaccurate at least to the extent that the cell resistance has both SOC dependent and SOC independent components. SOC estimates may not be accurate due at least to electrochemical and chemical reactions of electrode active materials with cell electrolyte, and mechanical disintegration and delamination of active materials for current collectors, as well as corrosion of cell components. These are complex reactions and have non-linear dynamic resistance components which are difficult to model.

Also, SOC measurements are often based on reading voltage, resistance, and temperature of the cell, combined with coulomb counting during cell operation. Model-based SOC estimators are complex and calculation intensive, as the source of voltage losses in the cell are not clear. It is also difficult to accurately determine various contributions of cell components to the value of SOC, such as activation overpotential, ohmic overpotential and concentration overpotential in an electrochemical cell. Ohmic overpotential has contributions from both electronic and ionic components and has a dynamic nature, as it changes due to modification of composition and structure of the electrode materials, as well as by the presence of parasitic reactions at electrode/electrolyte interfaces.

In the past, the SOC or “fuel gauge of the battery” has been monitored by empirical equations, and by coulomb counting, which is based on measuring flow of current and time duration in which current is flowing. However, this mode of operation often includes system calibrations and learning from previous steps of coulomb counting. Therefore, it is difficult to accurately add a complex correction factor such as cell aging effect. In fact, battery estimators based on electrochemical models often suffer from low accuracy and imposing artificial correction factors (non-physics based correction) to predict the cell state of charge.

Also, many models use a simple RC circuit to represent a battery with equivalent circuits. In one example, the battery modeling community uses a superposition integration algorithm to estimate SOC, state-of-health (SOH) and other performance parameters of various batteries including Li-ion, Ni-MH, and lead-acid batteries. In this type of modeling the input parameters are the cell open circuit voltage, cell resistance (usually high frequency resistance), charge transfer resistance, and capacitance associated with each electrode, as examples. In many cases for simplification and reducing mathematical treatment, they may use the same charge transfer resistance for both charge and discharge reactions, and similar diffusion coefficients for representing charge transport. In addition, a similar open circuit voltage may also be used for both charge and discharge, and hysteresis of the voltage profile during charge and discharge has typically been ignored in this type of modeling. More advanced electrochemical modeling uses a reduced algorithm for faster calculation of many sets of differential equations representing mass and charge conservation laws in electrodes and electrolytes, which still encounter many simplification and grouping of parameters to estimate battery SOC, SOH, and the like. The accuracy of these types of regression analysis is often not adequate and their degree of redundancy and reliability needs further improvements.

One important parameter in battery modeling is the thermal management modeling that is used to map heat generation in batteries. The thermal models typically include both entropy and enthalpy of chemical reactions in the cell and thermal conductivity of the cell components. This type of thermodynamic model may use a Ragone plot (cell specific power versus cell specific energy) which in this type of methodology can be misleading, due to a combination of heat sources that are SOC dependent and heat sources that are independent of cell SOC (such as chemical side reaction and the common self-discharge of the battery). Current thermal modeling strategy often uses equivalent circuit model that does not have sufficient accuracy and reliability to predict thermal behavior of cells and battery packs.

Another complication that arises from the use of an electrochemical model and impedance tracker method is that the cell parameters, such as cell impedance, is measured at a fixed frequency (often 1000 Hz). However, cell DC resistance is the meaningful parameter for cells and battery modeling, as the current flow through a cell or bank of cells is DC current. Therefore, BMS systems based on a cell impedance tracker may lead to erroneous results. In addition, the cell resistance may remain small while the capacity fading is still severe.

In addition to inaccurate SOC estimation and thermal management models, the current BMS is often inefficient in cell balancing, and a weak cell (in parallel and series string inside the battery pack) may limit the full utilization of useable SOC. If weaker cells are not isolated or balanced their performance can worsen and pull apart from the rest of the cells in the battery pack, leading to a fast degradation of battery performance.

In recent years, attention has been focused on developing non-electrochemical techniques to estimate battery SOC, due to the importance and benefit of having a reliable battery management system. Among the most advance developments, the use of fuzzy logic and a Kalman filter are often reported. These non-physics based approaches are calculation intensive and may have poor accuracy in estimating SOC and SOH.

Thus, although there are numerous BMS technologies that have been developed, each has its advantages and potential drawbacks. Traditionally such drawbacks have not presented overall problems or limitations to the general use of battery technologies. That is, because of their relatively massive or heavy nature, batteries have generally been used in stationary devices (where weight is not an issue), or in more limited capacity (such as a 12 Volt battery in conventional automobile or light truck applications) when compared to the more contemporary applications being considered. However, due to the tremendous new opportunities that the much lighter and more efficient lithium-ion batteries present (such as in mobile vehicles, lightweight computer devices, or in aerospace applications), it has become increasingly desirable to implement battery systems in new technologies from which batteries have traditionally been excluded.

And, given the industry-wide move into lightweight applications, it has become increasingly desirable to take full advantage of the full charge capability of batteries, and industries have been “pushing the envelope” in this regard. However, some exemplary well-publicized safety problems of large size batteries have been encountered on-board commercial planes, in vehicles, and in computing devices, due to poor charge management.

Therefore, to ensure safe operation, current lithium-ion batteries on board of hybrid electric vehicles (HEVs), plug-in hybrid electric vehicles (PHEVs), and electric vehicles (EVs) (and in other applications as well), are being under-utilized because of the inability to accurately estimate SOC, SOH, etc. That is, out of concerns for safety, conservative estimates are used by current BMS technologies, which results in utilization of the capacity of the batteries that is far from optimal. This inefficiency in utilization of battery full capacity, due to lack of an accurate battery management system, adds significant weight and cost to current systems. As such, Ni-MH batteries are used typically only within 30-50% of their SOC, and lithium-ion batteries may be used for instance within 25-55% of their SOC windows. This means 50% or more of the battery may remain as deadweight on the board of a vehicle or in other applications.

There is therefore tremendous interest to develop an accurate SOC estimator.

### BRIEF DESCRIPTION OF THE DRAWINGS

FIG. 1 is and illustration of a battery monitoring device that includes a coil positioned in a battery.

FIG. 2 illustrates a battery having first and second lithium cells.

FIG. 3 illustrates an arrangement in which both coils are positioned or embedded within the lithium cell.

FIG. 4 shows an arrangement in which a twin coil is used to charge a battery using twin coils positioned outside the battery.

FIG. 5 shows exemplary voltage profiles for both charge and discharge 504.

FIGS. 6A and 6B show illustrate exemplary normalized data in which voltage/current profiles are normalized to correspond to SOC.

FIG. 7 illustrates response curves of the second coil as a function of the numbers of charge/discharge cycles.

### DETAILED DESCRIPTION

Referring now to the discussion that follows and the drawings, illustrative approaches to the disclosed systems and methods are described in detail. Although the drawings represent some possible approaches, the drawings are not necessarily to scale and certain features may be exaggerated, removed, or partially sectioned to better illustrate and explain the present disclosure. Further, the descriptions set forth herein are not intended to be exhaustive, otherwise limit, or restrict the claims to the precise forms and configurations shown in the drawings and disclosed in the following detailed description.

This disclosure is directed toward a magneto-electrochemical sensor for lithium batteries, with the capability of determining a state-of-charge (SOC) for a lithium-ion battery based on an amount of Fe(II) and Fe(III). It is also possible to simultaneously estimate one or more of a battery state of life (SOL), a battery state of function (SOF), and internal battery temperature in real-time. Another aspect of this disclosure is to combine a BMS and magneto-electrochemical sensor components with a wireless battery charger. This combination of BMS and wireless charger will significantly reduce design complexity, and lower the overall cost of energy storage systems for electrification of automobiles.

One principle of this disclosure relies on measuring changes in the chemical composition-properties and magnetic behavior of battery electrode materials as a function of SOC and cell temperature. The associated battery parameters related to the cell SOC and cell temperature can be determined from the output of magneto-electrochemical sensor.

Also in this disclosure, Eddy current coupled with resistance (or impedance) measurement (R=V/I) in a cell is used to estimate both the battery SOC and SOH.

One goal is to develop a SOC estimator for advanced lithium batteries. One important operation of the disclosed SOC estimator is based on monitoring changes in one or more properties of electrode materials during charge and discharge processes, and correlating the change to the SOC of the battery. One parameter or property that changes as a function of SOC is the magnetic property of the electrode active materials.

In this disclosure, the use of other electrode material property changes, such as resistance, dielectric constant, volume-pressure, and optical properties during charge and discharge of a battery, may also be used to estimate battery SOC.

In the disclosed application and in addition to estimating or determining SOC, improvements include using magnetic property change as a detecting signal to monitor internal cell temperature, using an integrated printing coil to be part of battery current collector inside the cell that significantly improve signal to noise ratio detection, and using an integrated printed coil which is part of SOC estimator also as part of the battery charger unit. This disclosure also includes dual use of a current wireless charger as both BMS and the battery charger.

Application of a magneto-electrochemical sensor in aerospace industry may resolve current safety issues that the aerospace industries are facing, particularly for using large format lithium batteries on board of commercial planes. Thus, the disclosed sensors may be integrated in similar lithium cells that are compatible for the aerospace industry.

There is also significant market for lithium battery for un-manned planes, and the battery used in these types of applications also includes accurate management and control. The disclosed magneto-electrochemical sensors are also suitable for these classes of airplanes. The rugged high energy density battery used in un-manned planes can be equipped with the magneto-electrochemical sensors to increase their autonomous flight time.

There is a great market opportunity for a non-electrochemical sensor for battery management systems. The potential market for the SOC sensor in one example is for electric-based transportation. However, other market sectors such as electronics, cell phones, computers, shavers, power tools, and stationary energy storage back-up systems can also adopt and benefit form an accurate SOC estimator. The focus of this disclosure is on application of magneto-electrochemical sensor for transportation applications, however there are clearly many additional applications and this disclosure is not limited to any of the aforementioned applications.

The disclosed magneto-electrochemical sensor also can be used as a dynamic temperature sensor to monitor internal temperature of individual cells in the battery pack. This capability will allow further simplification of the current thermal management system in HEVs and EVs, as examples.

This disclosure introduces a sensor based on the principle of measuring temperature of the battery based on changes in magnetic property of electrode materials versus temperature. The dual use of wireless charger as both the battery management system and the charger may further expand marketability of our magneto-electrochemical wireless sensor. This disclosure also uses the embedded conductive coils as components of both SOC estimator and battery wireless charger.

Disclosed is a method and apparatus that includes using changes of magnetic susceptibility of battery materials versus temperature to be used as a sensor for estimating the battery internal temperature in real-time. Typically, magnetic susceptibility is defined as a dimensionless proportionality constant that indicates the degree of magnetization of a material in response to an applied magnetic field.

This disclosure includes the use of a non-electrochemical method based on magnetic and Eddy current measurements for SOC estimation. A description of the principle behind this development is given. The SOC of a lithium battery is a function of lithium concentration stored in the electrodes (i.e., x in LiₓFePO₄). Therefore by knowing the Li concentration, the SOC can be estimated. In addition, the concentration of Li ion in LiₓFePO4 is directly associated with the amount of Fe(III) converted to Fe(II), through the following relation. The cell reactions in lithium battery (Graphite/iron phosphate cell) is given as:

C₆+LiFePO₄⇄LiC₆+FePO₄ (Eqn. 1).

In this process Fe changes its oxidation state from Fe²⁺ to Fe³⁺, (also designated as Fe(II) and Fe(III)) hence, changes its magnetic behavior. This magnetic change is directly and linearly related to the amount of electrode conversion, which is a direct indication of the SOC of the battery. The magnetic behavior of the cell electrodes as a function of state of charge can be translated into a readable current response through inductive currents that can be easily monitored.

More specifically, the SOC of a lithium battery is a function of lithium concentration stored in the electrodes (i.e. x in LiₓFePO₄). Therefore by knowing the Li concentration, the SOC can be estimated. In addition, the concentration of Li ion in LiₓFePO4 is directly associated with the amount of Fe(III) converted to Fe(II), through the following relation:

LiFe(II)PO₄ [symbol] Liₓ[Fe(II)ₓFe(III)₁₋ₓ]PO₄+(1−x)Li⁺+(1−x)e (Eqn. 2).

Therefore the ratio of Fe(III)/Fe(II) is a measure of SOC. As known, iron is a magnetic material, and changes in Fe(III) to Fe(II) ratio is linearly related to the change in magnetic property of the LiₓFePO₄ cathode. Therefore magnetic measurement can be utilized to measure the SOC of a battery with a LiFePO4 cathode.

The principle Physics that is employed to monitor the magnetic change is based on a well-known inductive effect resulting from coupling of magnetic field, generated by the flow of current in a coil, and the induced current in the second coil similar to the principle operation of a transformer. However, the induced current in the second coil is affected by the magnetic property of the medium. As such, change in the magnetic property of the medium which is directly related to the SOC of the battery can be monitored—referred to as a “reverse transformer” effect. Measuring the changes of the induced current in the second coil as a function of SOC is one focus of this disclosure.

That is, this disclosure includes a physics-based approach to develop an estimator of battery SOC, similar to a fuel gauge used in the current combustion engine. The magnetic behavior of the cell electrodes as a function of SOC is translated into a readable current response through inductive and eddy currents that can be easily monitored. As the consumption and changes of battery active materials in batteries, during charge and discharge, are directly associated with the SOC of the battery, by monitoring these changes in real-time using magnetic measurement the real battery SOC can be estimated.

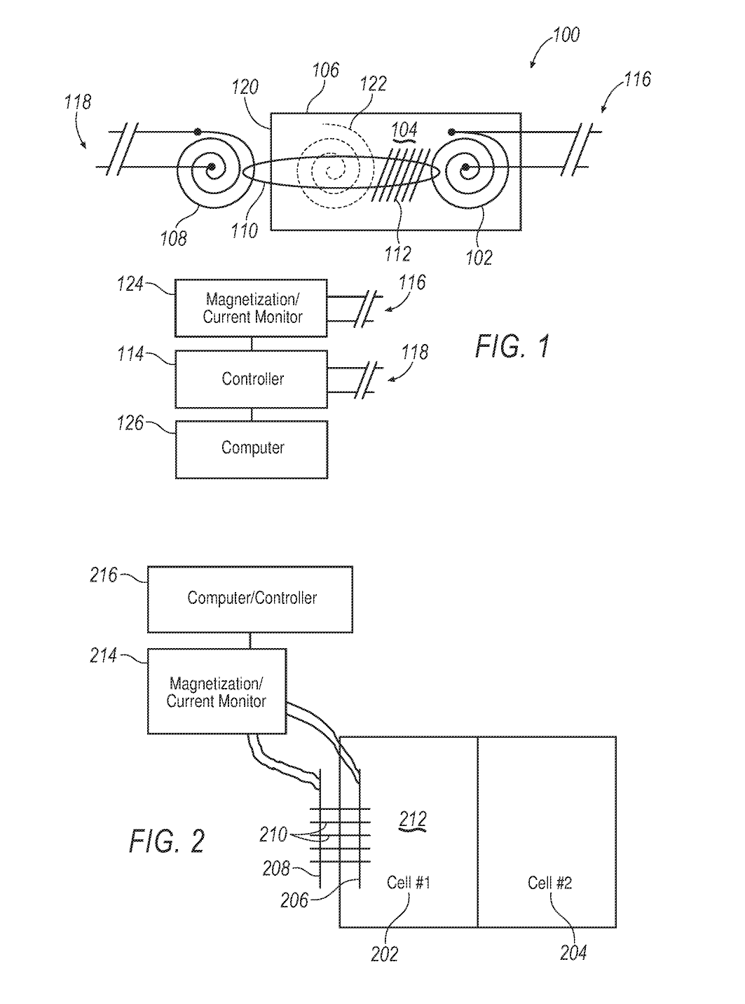

Referring to FIG. 1, a battery monitoring device 100 includes a first coil 102 positioned within a cell 104 of a battery 106. A second coil 108 is positioned to be magnetically coupled 110 to the first coil 102 through active material 112 that is contained within the cell 104. A controller 114 is configured to apply an electrical current 116 to the first coil 102, detect induced electrical current 118 in the second coil 108, and determine a state-of-charge (SOC) of the battery 106 based on the induced electrical current 118. And, coils 102, 108 are shown in a planar view for illustration purposes. However, it is contemplated that in one example coils 102, 108 face each other along general planar surfaces of each coil, which can enhance the coupling effect therebetween.

In the example illustrated in FIG. 1, it is shown that electrical current 116 is applied to first coil 102. However, it is contemplated that electrical current 116 may instead be applied to second coil 108 instead of first coil 102, in which case the induced current is detected in first coil 102. That is, so long as electrical current is applied to one of coils 102, 108, and an induced current generated by the other of coils 102, 108 may be received after having passed as magnetization through active material 112, then the SOC of battery 106 may be determined. Also, it is to be understood that active material 112, shown in only a portion of cell 104 for illustration purposes, is actually typically distributed throughout all of cell 104, or multiple cells of battery 106. Thus, as battery 106 is charged and discharged, its mixture of Fe(III) and Fe(II) changes, accordingly. Thus, controller 114 or computer 126 may thereby use the mixture or ratio of Fe(III) to Fe(II) to determine SOC based, in one example, on a linear relationship between Fe(III) and Fe(II).

In one example, measurements may be calibrated such that current induced in one of the coils after having been applied to the other coil can be correlated to the SOC. In general, when approximately 100% of Fe(III) is present in an active material, then the battery is 100% charged. And, when 100% of Fe(II) is present in an active material, then the battery is 100% discharged. A linear relationship may be assumed between the two extremes of 100% Fe(III) and 100% Fe(II), which to first order provides a linear relationship from which the SOC can be determined, in real-time and as the SOC changes with charge or discharge.

Further, in the example of FIG. 1, second coil 108 is illustrated as being positioned external to battery 106. However, it is contemplated that second coil 108 may be attached to an outer surface 120 of battery 106. In an alternate embodiment, instead of positioning second coil 108 external to battery 106, it is contemplated that second coil may be positioned within battery 106 and in its alternate location 122 (shown in phantom). As such and as stated, so long as the induced current detected in one of the coils is a result of magnetization having passed through active material 112, then the SOC of battery 106 may be determined.

In addition, a magnetization/current monitor 124 is shown in which electrical current 116 is generated (passing to one of coils 102, 108), and in which induced electrical current 118 is measured. Magnetization/current monitor 124 may be controlled by controller 114, which in turn may receive instructions from a computer 126. It is contemplated that monitor 124, controller 114, and computer 126 may be separate components as illustrated, or that some of all of monitor 124, controller 114, and computer 126 may be provided in a single device that provides the functionality to determine the SOC of battery 106. It is also contemplated that, although battery 106 is illustrated having one cell 104, battery 106 may include multiple cells, each of which may be monitored independently, in one example, and for which individual SOCs may be determined.

FIGS. 2-4 illustrate additional exemplary arrangements according to the disclosure. For instance, FIG. 2 illustrates a battery 200 having a first cell 202 and a second cell 204, which are exemplary representations of two cells of what may be a plurality of lithium cells. A first coil 206 is positioned within first cell 202, and a second coil 208 is positioned external to battery 200, and first coil 206 and second coil 208 are coupled to one another via a magnetic coupling 210. That is, and as illustrated with respect to FIG. 1, magnetic coupling 208 results from an AC current applied to first coil 206, which induces a current in second coil 208. The magnetic coupling 208 passes through at least a portion of active material 212 in first cell 202. The first and second coils 206, 208 are electrically connected to a magnetization/current monitor 214, and a computer/controller 216 monitors current flow in second coil 208 that is induced from an AC current having been applied to first coil 206. Thus, in operation, AC current applied to the first coil 206 is detected in the second coil 208 due to the magnetic coupling 210 therebetween. That is, magnetic change based on the inductive effect resulting from coupling of magnetic field, generated by the flow of current in the first coil, is detected as the induced current in the second coil. The induced current in the second coil is affected by the magnetic property of the medium (its Fe(II) and Fe(III) content), and the change in the magnetic property of the medium or active material 212 is directly related to the SOC of the battery 200.

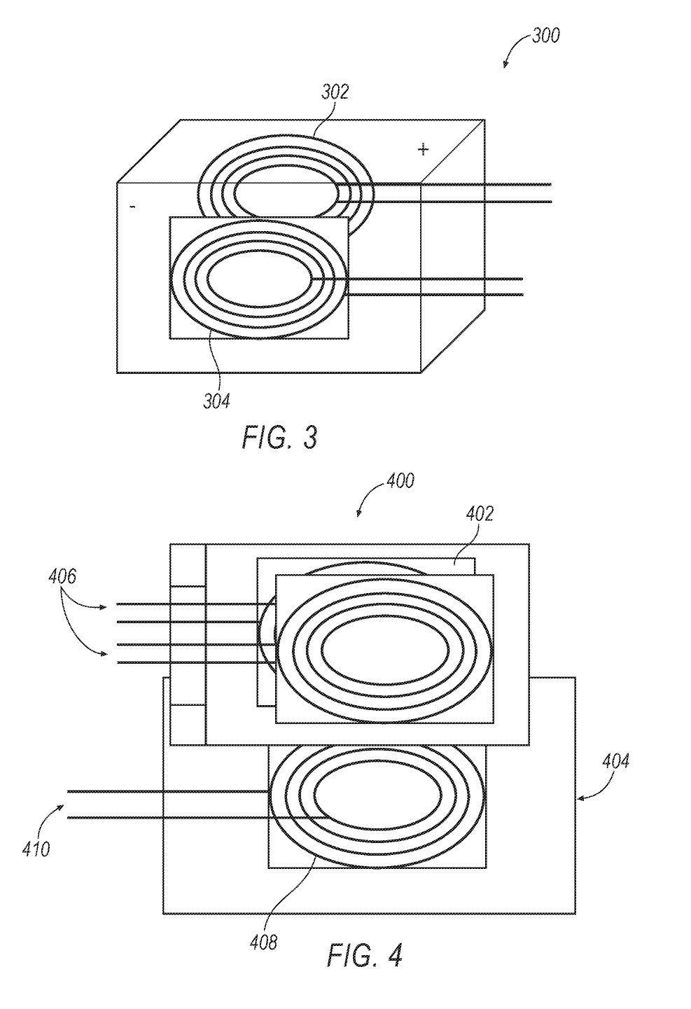

FIG. 3 illustrates another exemplary arrangement 300 in which both coils (illustrated as elements 302 and 304) are positioned or embedded within the lithium cell. First coil 302 and second coil 304 are positioned within the cell and coupled to one another, having their generally planar surfaces facing one another, via a magnetic coupling (coupling not shown in FIG. 3). The coils 302, 304 are electrically connected to a magnetization/current monitor (not shown) and a computer (not shown) monitors current flow in one coil (302 or 304) as a result of current being applied to the other coil (302 or 304). Thus, in operation, AC current applied to one of the coils is detected in the other coil due to the magnetic coupling therebetween. As such, a magnetic change based on the inductive effect resulting from coupling of magnetic field, generated by the flow of current in the one coil, is detected as the induced current in the other coil. The induced current is affected by the magnetic property of the medium—hence change in the magnetic property of the medium which is directly related to the SOC of the battery can be monitored.

FIG. 4 shows an arrangement 400 in which a twin coil 402 is used to charge a battery 404 using twin coils 402 positioned outside the battery. That is, current applied 406 to each or twin coils 402 may be used to induce a current in a coil 408 positioned within battery 404, which can charge battery 404, and which may be read as induced current 410. Thus, not only can SOC be monitored in the fashion described above (using the coupling and the change in magnetization of the medium), but the embedded coil within the battery may be used also to wirelessly charge the battery by using the magnetic coupling (not shown).

Thus, the above disclosure is extended to use an embedded coil in a battery to serve as a component of a wireless charger. The current wireless technology pads for cell phones and other small devices is a mature technology. The disclosed embedded coil-in-cell may be used to charge the cells in battery pack, based on similar physical principle that is currently used in charger pads. This dual use of wireless charger may reduce the complexity of current battery management systems. Also disclosed is the concept of dynamic cell balancing and will monitor the SOC (or SOH) of the device as correlated quantities versus response of the disclosed magneto-electrochemical sensor.

As such, the disclosed approach has the advantage over a traditional battery SOC estimator, which are mainly based on cell impedance tracking, coulomb counting method with read-up tables, or sophisticated electrochemical simulation models (which use fast computing and solving multi partial differential equations), as examples.

The disclosed principle of using magneto-electrochemical sensors is applicable for electrification of both the auto aerospace and marine industries. The cell form factors and cell chemistries used in these industries are compatible with the magneto-electrochemical sensors.

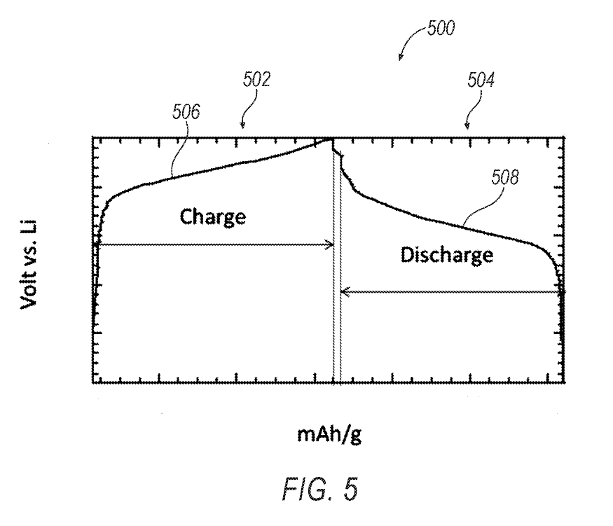

Referring now to FIG. 5, exemplary voltage profiles 500 for both charge 502 and discharge 504 are shown. As shown therein, each profile 502, 504 includes an approximately linear portion 506, 508, for the resultant voltage and as a function of current.

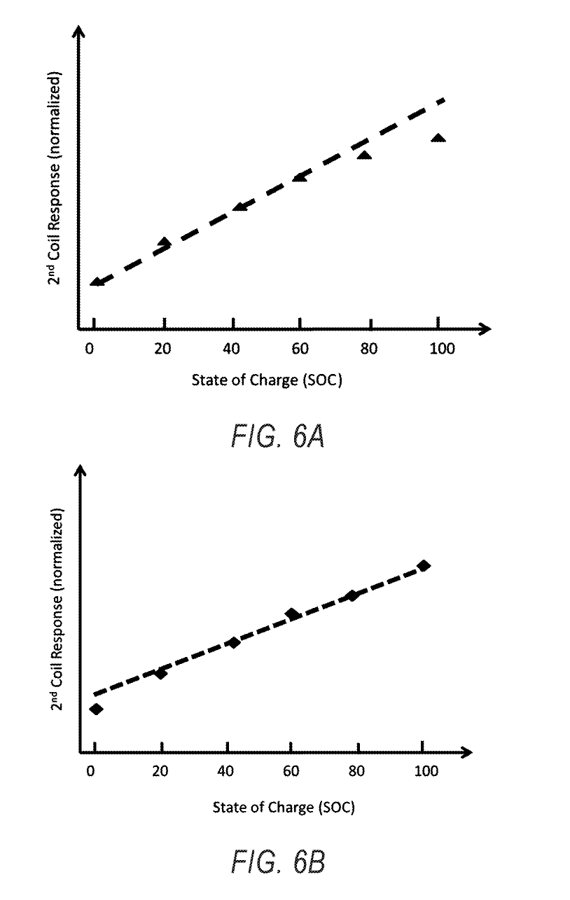

FIGS. 6A and 6B thereby show exemplary normalized data in which voltage/current profiles are normalized to correspond to SOC. The response of electrode during charge and discharge is recorded in FIGS. 6A and 6B. The linear behavior of the sensor response indicates transformation of electrode materials between two states of magnetization. The sensor response is calibrated and normalized. The sensor response in not linear versus frequency of AC applied signal. Therefore a sweet spot for frequency can be determined. Thus, as derived from the voltage/current profiles, SOC is correlated with the second coil response which, as described above.

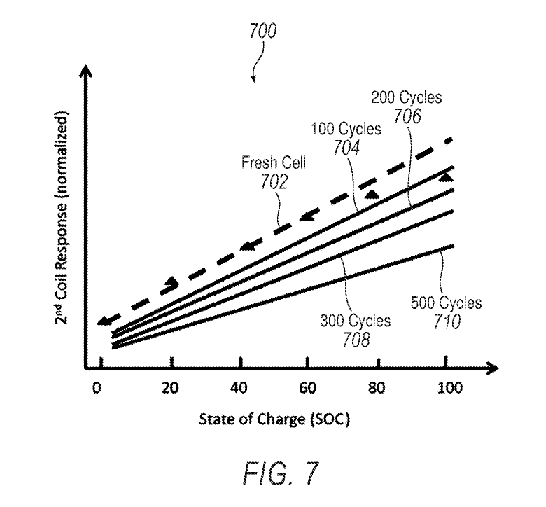

In addition, referring to FIG. 7, response curves 700 of the second coil can provide an indication of the sensor response as a function of the numbers of charge/discharge cycles. A fresh cell generally includes a higher indication of coil response 702, which diminishes with use over 100, 200, 300, and 500 cycles (illustrated respectively as elements 704, 706, 708, and 710). Accordingly, as the battery ages and loses the ability to charge and discharge to the same degree, the response curves (reflect in elements 704, 706, 708, and 710 and in a decrease in coil response), a general state of health (SOH) of the battery may be determined in which, not only battery degradation may be objectively quantified and monitored over time, but may also provide an ability to predict when failure of the battery will occur.

### Proof of Concept

For overall proof of concept, various phases of pure battery electrode materials have been synthesized and measured, as well as their magnetic responses as a function of their state of charge in a wide temperature range (−40 to 60° C.). Excellent linearity was observed between magnetic responses of the battery electrodes versus their state of charge. Also studied is the effect of electrode loading (thickness of active material on electrode current collector) and found linearity of magnetic response versus SOC when the sensor properly integrated in the electrode, in one example on electrode current collector.

To prove the concept that magnetic property change of an electrode in a lithium battery can be used to estimate SOC of the battery, the following tests were performed:
1. Successfully prepared phase pure electrode material with high quality for battery application.
2. Developed electrode formulation for electrode casting and prepared functioning electrodes.
3. Integrated twin copper coil sensor on electrode current collector, and also used commercial coil designed for wireless charger.
4. Fabricate lithium cells with embedded sensor in prismatic, flat full cell, containing positive and negative electrodes separated by a membrane soaked in electrolyte
5. Obtained multiple charge—discharge cycles of the cell and collected voltage profiles as well as capacity of the cell as a function of SOC
6. Monitored battery SOC using embedded twin coil in the cell. This is the first time that SOC is being monitored with embedded coil inside the cell on current collector architect.
7. Successfully proved the original concept, that change in magnetic property of the battery components can be used to monitor battery state of charge.
8. Successfully proved that a twin coil sensor can be used to monitor battery state of health (SOH) or rate of battery degradation during its cycle life. The sensor responses were monitored at each 20% interval of state of charge during multiple cycles.

That is, the changes of current response in second coil normalized to the response of fresh cell correlate well with the capacity degradation and SOH of the cell. Twin wire coils were embedded in the cell, (coated on the electrode current collector). This new electrode architecture that contains embedded coil is used for the construction of lithium cells.

In another example commercial wire coils attached to the current collector for monitoring the SOC of the battery by measuring the magnitude of the induced current in the second coil.

Electrode material, the cathode, was also prepared through solid state synthesis. The characterization of the electrode material has shown that phase pure cathode materials were formed. The cathode material was formulated into a paste with conductive carbon contain (0-15%) carbon nanofiber for coating on the above current collector to serve as the electrode active material in the lithium cell.

Also fabricated were lithium cells by putting the cathode against a counter electrode (the anode, graphite) separated by a separator containing electrolyte. The package was sealed inside a glove box containing inert atmosphere (Argon gas). The cell was charged and discharged at each of 5 intervals of state of charges (20% intervals) from zero state of charge (fully discharged cell) to fully charged state (100% state of charge). At each state of charge the response of the second coil was monitored when passing current signal through the first coil. The responses of the second coil were normalized based on its first response (response of fully discharged cell).

Changes were observed in the chemical composition of the electrode (cathode) during charge and discharge that can be monitored by the principle of the magneto—electrochemical effect, as described above. In addition, changes of the sensor response were observed as a function of cell cycling (degradation).

Thus, the proof of concept is demonstrated, and the visibility of using a magneto-electrochemical sensor and the Eddy current for SOC measurement.

Preparation of Cathode Material, Lithium Iron Phosphate

Lithium iron phosphate is prepared by mixing the corresponding precursors, lithium acetate, iron acetate and mono basic ammonium phosphate. The doping level of (0-5%), and up to 2% yttrium in one example, was used for further improvement of materials conductivity. The mixing is performed by energetic ball milling for 1-hour. The mixture was annealed under atmosphere (Argon+0-10% hydrocarbon, CH₄ in one example) for 4 hours at 650° C. After cooling the sample was ground and stored for later application.

The Electrode Formulation

Electrode paste was formulated by mixing 85 weight % electrode active material (LiFePO₄), with 15% conductive carbon (supper P-carbon nanofiber), and 5% elastomer binder dissolved in NMP solvent. The paste was applied to the electrode current collector using a Drawdown technique. The gap of the Drawdown technique was adjusted to produce about 100 microns thick electrode.

Fabrication of Embedded Twin Coil on Current Collector; The conductive coils (copper, in one example) were deposited using sputtering technique with (1-10 micron thick) using mask technology.

Fabrication of copper coated conductive coils were also performed using electroless plating technique, with a thin-layer of PVdF overcoat.

Commercial copper coils made for wireless charging attached on the current collector before coating the active material using elastomer binder.

An embedded coil of current collector was prepared by sputtering technique. A mask with twin coil pattern was made from plastic using laser patterning was used. The twin copper coil patterns were produced by attaching the mask on the current collector and sputtering copper on the mask. Removal of the mask produced the needed twin coil. The access to the twin coil was patterned to be close to the electrode tabs. This configuration allows easy sealing of the cell from the top with no electrolyte leakage. The entire cell was embedded in a prismatic, flat cell configuration.

Twin coils are fabricated also on both the positive and the negative current collectors where the coils were facing each other, as shown in FIG. 3.

In addition, the magnetic measurement also may serve as a device to monitor the battery temperature in real-time. The magnetic susceptibility of the battery electrode materials changes with temperature and this principle may be used to simultaneously monitor both the SOC and the cell internal temperature.

The disclosure also includes integration of a printed circuit coil within the cell that can sense and monitor magnetic changes in the cell as a function of state of charge. This embedded coil in cells will serve as the sensor for simultaneously measuring cell SOC and cell internal temperature.

Application of Eddy Current as Battery SOC and SOH Estimators

The embedded coil in a battery under load will generate Eddy current when current passed through the coil. The generated Eddy current is detected by the second coil and used as SOC and SOH estimators. The amplitude of the detected Eddy current in second coil is correlated with the resistance and chemical nature of the electrode between or nearby the coils. The chemical nature of the materials (electrode materials) between the coils will affect the magnitude of the Eddy current induced to the second coil. As the chemical nature of the electrode (composition) changes during charge-discharge of a battery, the magnitude of the detected Eddy current follows the variation of electrode composition. The correlation between the change in induced current by the generated Eddy current and the composition of the electrode material (SOC) is used to estimate the battery SOC. The induced Eddy current also can be used to monitor the resistance buildup in the cell during charge-discharge which is related to the capacity fading and state of health of the battery. In this disclosure, the Eddy current coupled with resistance (or impedance) measurement (R=V/I) in the cell is used to estimate both the battery SOC and SOH.

This disclosure also introduces battery electrodes with embedded coil printed or attached to the electrode current collector(s). This disclosure uses the embedded coil in battery as a source generator or as a detector of a perturbation. Perturbations can be in the form of passing current through the first coil, or perturbation from another source nearby (i.e. components that generate Eddy or stray current).

This disclosure uses changes in detector response as function of changes in battery materials which are associated with the battery SOC and SOH.

Various geometries of coils and loops of wires (ribbons) can be designed to generate Eddy current (i.e. circular, rectangle loops, square loops, etc.) with different number of turns, length, and format. The magnitude of the Eddy current can be optimized by the magnitude of the AC current passed through the coil. The amplitude of the Eddy current is inversely proportional to the resistance of the materials.

Computing devices such as controller 114 or computer 126 may employ any of a number of computer operating systems known to those skilled in the art, including, but by no means limited to, microprocessor systems, such as those manufactured by Motorola and Intel. The controller 114 or computer 126 may also employ known versions and/or varieties of the Microsoft Windows® operating system, the Unix operating system (e.g., the Solaris® operating system distributed by Oracle Corporation of Redwood Shores, Calif.), the AIX UNIX operating system distributed by International Business Machines of Armonk, N.Y., and the Linux operating system. Computing devices may include any one of a number of computing devices known to those skilled in the art, including, without limitation, a computer workstation, a desktop, notebook, laptop, or handheld computer, or some other computing device known to those skilled in the art.

Computing devices such as the foregoing generally each include instructions executable by one or more computing devices such as those listed above. Computer-executable instructions may be compiled or interpreted from computer programs created using a variety of programming languages and/or technologies known to those skilled in the art, including, without limitation, and either alone or in combination, Java™, C, C++, Visual Basic, Java Script, Perl, etc. In general, a processor (e.g., a microprocessor) receives instructions, e.g., from a memory, a computer-readable medium, etc., and executes these instructions, thereby performing one or more processes, including one or more of the processes described herein. Such instructions and other data may be stored and transmitted using a variety of known computer-readable media.

A computer-readable medium includes any medium that participates in providing data (e.g., instructions), which may be read by a computer. Such a medium may take many forms, including, but not limited to, non-volatile media, volatile media, and transmission media. Non-volatile media include, for example, optical or magnetic disks and other persistent memory. Volatile media include dynamic random access memory (DRAM), which typically constitutes a main memory. Transmission media include coaxial cables, copper wire and fiber optics, including the wires that comprise a system bus coupled to the processor. Transmission media may include or convey acoustic waves, light waves and electromagnetic emissions, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, a carrier wave as described hereinafter, or any other tangible medium from which a computer can read.

It is intended that the scope of the present methods and apparatuses be defined by the following claims. However, it must be understood that the disclosed system may be practiced otherwise than is specifically explained and illustrated without departing from its spirit or scope. It should be understood by those skilled in the art that various alternatives to the configuration described herein may be employed in practicing the claims without departing from the spirit and scope as defined in the following claims. The scope of the disclosure should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future examples.

Furthermore, all terms used in the claims are intended to be given their broadest reasonable constructions and their ordinary meanings as understood by those skilled in the art unless an explicit indication to the contrary is made herein. In particular, use of the singular articles such as “a,” “the,” “said,” etc., should be read to recite one or more of the indicated elements unless a claim recites an explicit limitation to the contrary. It is intended that the following claims define the scope of the device and that the method and apparatus within the scope of these claims and their equivalents be covered thereby. In sum, it should be understood that the device is capable of modification and variation and is limited only by the following claims.

1. A battery monitoring device, comprising:
a first coil positioned within a cell of a battery;
a second coil positioned to be magnetically coupled to the first coil through active material that is contained within the cell; and
a controller configured to:
apply an electrical current to one of the first and second coils;
detect induced electrical current in the other of the first and second coils; and
determine a state-of-charge (SOC) of the battery based on the induced electrical current.

2. The battery monitoring device of claim 1, wherein the controller is configured to:
determine an amount of Fe(II) and Fe(III) in the active material based on the induced electrical current; and
determine the SOC of the battery based on the amount of Fe(II) and Fe(III).

3. The battery monitoring device of claim 2, wherein the controller is configured to determine the SOC based on linear proportions of the amounts of Fe(II) and Fe(III).

4. The battery monitoring device of claim 1, wherein the second coil is positioned within the cell of the battery.

5. The battery monitoring device of claim 1, wherein the second coil is positioned external to the cell of the battery.

6. The battery monitoring device of claim 5, wherein the controller is further configured to apply a current to the second coil to inductively charge the battery via the first coil.

7. The battery monitoring device of claim 1, wherein the battery is a lithium-ion battery.

8. The battery monitoring device of claim 1, wherein the first coil is positioned on a current collector within the cell of the battery.

9. The battery monitoring device of claim 1, wherein the applied electrical current is an AC current.

10. The battery monitoring device of claim 1, wherein the controller is configured to monitor the SOC of the battery during usage of the battery.

11. A method of determining a state-of-charge (SOC) of a battery, comprising:
passing a first current through a first coil;
measuring a second current in a second coil that is induced by the first current in the first coil after having passed as a magnetization through a magnetic medium that includes at least a portion of the battery;
determining a SOC of the battery based on the measured second current.

12. The method of claim 11, further comprising:
determining an amount of Fe(II) and Fe(III) in the magnetic medium in the battery based on the measured second current; and
determining a state-of-charge (SOC) of the battery based on the amount of Fe(II) and Fe(III).

13. The method of claim 12, further comprising determining the SOC based on linear proportions of the amounts of Fe(II) and Fe(III).

14. The method of claim 11, wherein the second coil is positioned within the portion of the battery.

15. The method of claim 11, wherein the second coil is positioned external to the cell of the battery.

16. The method of claim 15, further comprising applying a current to the second coil to inductively charge the battery via the first coil.

17. The method of claim 11, wherein the battery is a lithium-ion battery.

18. The method of claim 11, wherein the first coil is positioned on a current collector within the cell of the battery.

19. The method of claim 11, wherein the applied electrical current is an AC current.

20. The method of claim 1, further comprising monitoring the SOC of the battery during usage of the battery.
